(19) United States
(12) Patent Application Publication
(10) Pub. No.: US 2026/0026197 A1
(43) Pub. Date: Jan. 22, 2026

(54) DISPLAY SUBSTRATE AND DISPLAY SCREEN

(71) Applicants: Beijing BOE Technology Development Co., Ltd., Beijing (CN); BOE TECHNOLOGY GROUP CO., LTD., Beijing (CN)

(72) Inventors: Wenqi Liu, Beijing (CN); Yutong Yan, Beijing (CN); Xiaohu Li, Beijing (CN); Zhongyuan Sun, Beijing (CN); Mengna Sun, Beijing (CN); Zhiqiang Jiao, Beijing (CN); Hongli Wang, Beijing (CN); Xu Liu, Beijing (CN); Tong Wu, Beijing (CN)

(73) Assignees: Beijing BOE Technology Development Co., Ltd., Beijing (CN); BOE TECHNOLOGY GROUP CO., LTD., Beijing (CN)

(21) Appl. No.: 18/994,797

(22) PCT Filed: May 17, 2024
(86) PCT No.: PCT/CN2024/093834

§ 371 Date: Jan. 15, 2025

(30) Foreign Application Priority Data
Jun. 16, 2023 (CN) 202310720543.X

(51) Int. Cl. H10K 59/122; H10K 59/35; H10K 59/80

(52) U.S. Cl. CPC H10K 59/122; H10K 59/873; H10K 59/878; H10K 59/879; H10K 59/353

(57) ABSTRACT

A display substrate and a display screen are provided. A trapezoidal reflection structure is arranged on a TFE layer, a low-refractive-index reflection layer is arranged on the trapezoidal reflection structure, a high-refractive-index reflection layer is arranged on the low-refractive-index reflection layer, and a cover plate is attached. In a case that light is reflected by the high-refractive-index reflection layer toward the low-refractive-index reflection layer, due to a difference between refractive indices, a part of the light is totally reflected after an incident angle is greater than a critical angle. The low-refractive-index reflection layer serves as a condensing lens to change large-angle transverse light into active forward light, so as to improve the light transmittance of the display substrate, and increase the brightness at a front viewing angle.

### CROSS-REFERENCE TO RELATED APPLICATION

This application claims a priority of the Chinese patent application No. 202310720543.X filed on Jun. 16, 2023, which is incorporated herein by reference in its entity.

### TECHNICAL FIELD

The present disclosure relates to the field of electronic technology, in particular to a display substrate and a display screen.

### BACKGROUND

An Organic Light-Emitting Diode (OLED) element has widely applied due such advantages as being light, thin, sensitive and colorful. Currently, the OLED element has such problems as low blue-light efficiency and a short service life. In addition, the external quantum efficiency of the OLED element is very low, usually smaller than 20%. In several light loss modes, a waveguide effect accounts for a very large part, so there is an urgent need to improve light transmittance of the display substrate and increase brightness at a front viewing angle.

### SUMMARY

An object of the present disclosure is to provide a display substrate and a display screen, so as to improve the light transmittance of the display substrate and increase the brightness at the front viewing angle. The present disclosure provides the following technical solutions.

In one aspect, the present disclosure provides in some embodiments a display substrate, including a back plate layer, a pixel layer, a cathode layer, a thin film encapsulation layer, a trapezoidal reflection structural layer, a low-refractive-index reflection layer, a high-refractive-index reflection layer, and a cover plate layer. The pixel layer includes a pixel light-emitting structure and a pixel definition layer. The pixel layer is arranged on the back plate layer, the cathode layer is arranged at a side of the pixel layer distal to the back plate layer, the thin film encapsulation layer is arranged at a side of the cathode layer distal to the back plate layer, the trapezoidal reflection structural layer is arranged at a side of the thin film encapsulation layer distal to the back plate layer, an orthogonal projection of the trapezoidal reflection structural layer onto the back plate layer overlaps with an orthogonal projection of the pixel definition layer onto the back plate layer, the low-refractive-index reflection layer is arranged at a side of the trapezoidal reflection structural layer and a side of the thin film encapsulation layer distal to the back plate layer, and the high-refractive-index reflection layer is arranged at a side of the low-refractive-index reflection layer distal to the back plate layer. A refractive index of the low-refractive-index reflection layer is smaller than a first refractive index threshold, a refractive index of the high-refractive-index reflection layer is greater than a second refractive index threshold, and the second refractive index threshold is greater than the first refractive index threshold.

In a possible embodiment of the present disclosure, in a plane perpendicular to the back plate layer, the trapezoidal reflection structural layer includes a plurality of trapezoidal reflection structures, each of the trapezoidal reflection structures includes a lower base proximate to the back plate layer and an upper base distal to the back plate layer, and a length of the upper base is smaller than a length of the lower base.

In a possible embodiment of the present disclosure, the refractive index of the low-refractive-index reflection layer is within a range of 1.2 to 1.5.

In a possible embodiment of the present disclosure, the refractive index of the high-refractive-index reflection layer is not smaller than 1.7.

In a possible embodiment of the present disclosure, a difference between the refractive index of the high-refractive-index reflection layer and the refractive index of the low-refractive-index reflection layer is not smaller than 0.3.

In a possible embodiment of the present disclosure, the low-refractive-index reflection layer includes SiO₂, LiF or MgF₂.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures. A length of a lower base of the trapezoidal reflection structure corresponding to the B pixel light-emitting structure is not smaller than a length of a lower base of the trapezoidal reflection structure corresponding to the R pixel light-emitting structure, and the length of the lower base of the trapezoidal reflection structure corresponding to the R pixel light-emitting structure is not smaller than a length of a lower base of the trapezoidal structure corresponding to the G pixel light-emitting structure. For each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

In a possible embodiment of the present disclosure, ½ pitch≤W2≤W1≤W3≤pitch, where W1 represents the length of the lower base of the trapezoidal reflection structure corresponding to the R pixel light-emitting structure, W2 represents the length of the lower base of the trapezoidal reflection structure corresponding to the G pixel light-emitting structure, W3 represents the length of the lower base of the trapezoidal reflection structure corresponding to the B pixel light-emitting structure, and pitch represents a length of a lower base of the pixel definition layer.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures. A base angle of the trapezoidal reflection structure corresponding to the B pixel light-emitting structure is not greater than a base angle of the trapezoidal reflection structure corresponding to the R pixel light-emitting structure, the base angle of the trapezoidal reflection structure corresponding to the R pixel light-emitting structure is not greater than a base angle of the trapezoidal structure corresponding to the G pixel light-emitting structure, and two base angles of the trapezoidal reflection structure are equal. For each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

In a possible embodiment of the present disclosure, 35°≤θ3≤θ1≤θ2≤80°, where θ1 represents the base angle of the trapezoidal reflection structure corresponding to the R pixel light-emitting structure, θ2 represents the base angle of the trapezoidal reflection structure corresponding to the G pixel light-emitting structure, and θ3 represents the base angle of the trapezoidal reflection structure corresponding to the B pixel light-emitting structure.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures. A base angle of the B pixel light-emitting structure is not greater than a base angle of the R pixel light-emitting structure, and the base angle of the R pixel light-emitting structure is not greater than a base angle of the G pixel light-emitting structure. For each of the pixel light-emitting structures, the base angles of the pixel light-emitting structure include a second-side base angle of the trapezoidal reflection structure corresponding to the pixel definition layer at a first side of the pixel light-emitting structure in a vertical direction and a first-side base angle of the trapezoidal reflection structure corresponding to the pixel definition layer at a second side of the pixel light-emitting structure in the vertical direction, and for each of the pixel definition layers, an orthogonal projection of the trapezoidal reflection structure corresponding to the pixel definition layer in the vertical direction to the back plate layer overlaps with an orthogonal projection of the pixel definition layer onto the back plate layer.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures. A height of the trapezoidal reflection structure corresponding to the B pixel light-emitting structure is not smaller than a height of the trapezoidal reflection structure corresponding to the R pixel light-emitting structure, and the height of the trapezoidal reflection structure corresponding to the R pixel light-emitting structure is not smaller than a height of the trapezoidal reflection structure corresponding to the G pixel light-emitting structure. For each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

In a possible embodiment of the present disclosure, 1 μm≤h2≤h1≤h3≤10 μm, where h1 represents the height of the trapezoidal reflection structure corresponding to the R pixel light-emitting structure, h2 represents the height of the trapezoidal reflection structure corresponding to the G pixel light-emitting structure, and h3 represents the height of the trapezoidal reflection structure corresponding to the B pixel light-emitting structure.

In another aspect, the present disclosure provides in some embodiments a display screen including the above-mentioned display substrate.

The present disclosure has the following beneficial effects.

According to the display substrate and the display screen in the embodiments of the present disclosure, the trapezoidal reflection structure is arranged on the TFE, the low-refractive-index reflection layer is arranged on the trapezoidal reflection structure, the high-refractive-index reflection layer is arranged on the low-refractive-index reflection layer, and then the cover plate is attached. In a case that light is reflected by the high-refractive-index reflection layer toward the low-refractive-index reflection layer, due to a difference between the refractive indices, a part of the light is totally reflected after an incident angle is greater than a critical angle. Hence, the low-refractive-index reflection layer serves as a condensing lens to change large-angle transverse light into active forward light. As a result, it is able to improve the light transmittance of the display substrate, and increase the brightness at a front viewing angle.

Of course, any product or method in the embodiments of the present disclosure does not need to achieve all the above-mentioned advantages.

### BRIEF DESCRIPTION OF THE DRAWINGS

In order to illustrate the technical solutions of the present disclosure in a clearer manner, the drawings desired for the present disclosure will be described hereinafter briefly. Obviously, the following drawings merely relate to some embodiments of the present disclosure, and based on these drawings, a person skilled in the art may obtain the other drawings without any creative effort.

FIG. 1 is a schematic view showing a conventional display substrate;

FIG. 2-1 is a schematic view showing a display substrate according to one embodiment of the present disclosure;

FIG. 2-2 is a top view of the display substrate according to one embodiment of the present disclosure;

FIG. 3-1 is a schematic view showing a principle of an optical path according to one embodiment of the present disclosure;

FIG. 3-2 is a curve diagram of a simulation effect according to one embodiment of the present disclosure;

FIG. 4-1 is a curve diagram of a simulation gain according to one embodiment of the present disclosure;

FIG. 4-2 is another schematic view showing the display substrate according to one embodiment of the present disclosure;

FIG. 5-1 is another curve diagram of the simulation gain according to one embodiment of the present disclosure;

FIG. 5-2 is yet another schematic view showing the display substrate according to one embodiment of the present disclosure;

FIG. 6 is still yet another schematic view showing the display substrate according to one embodiment of the present disclosure;

FIG. 7-1 is yet another curve diagram of the simulation gain according to one embodiment of the present disclosure; and

FIG. 7-2 is still yet another schematic view showing the display substrate according to one embodiment of the present disclosure.

### REFERENCE SIGN LIST

01 back plate layer
02 pixel definition layer
03 pixel light-emitting structure
04 cathode layer
05 thin film encapsulation layer
06 trapezoidal reflection structural layer
07 low-refractive-index reflection layer
08 high-refractive-index reflection layer
09 cover plate layer

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

In the related art, as shown in FIG. 1, a display substrate includes a Thin Film Transistor (TFT) layer, an OLED-Red (R) light-emitting structure, an OLED-Green (G) light-emitting structure, an OLED-Blue (B) light-emitting structure, a cathode layer, a Thin Film Encapsulation (TFE) layer, an encapsulation sealant, and a glass cover plate layer. Based on a refraction law, absorption and a waveguide effect occur for light generated by the OLED between film layers whose refractive indices are greatly different from each other. At this time, the light is constrained in the structural layer, and thereby the light transmittance of the OLED is reduced.

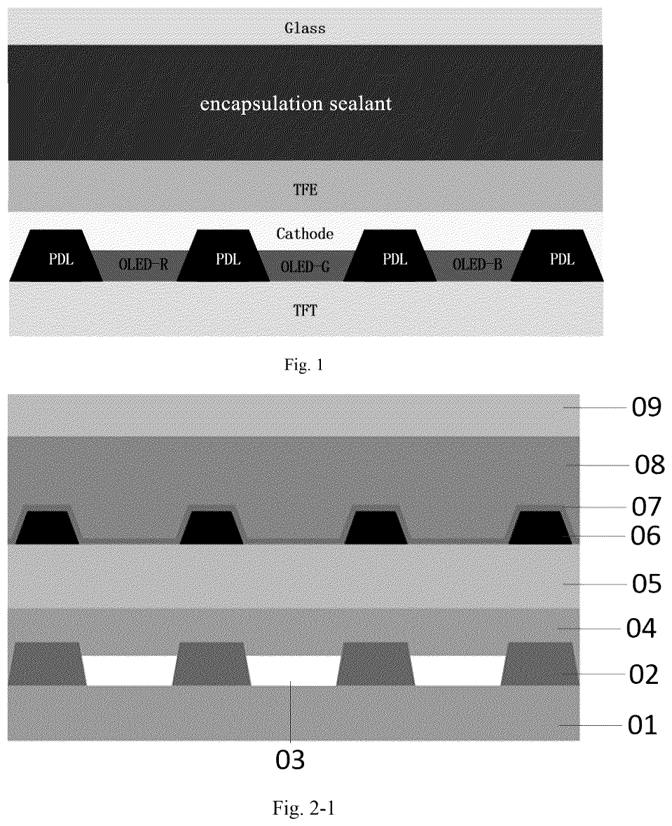

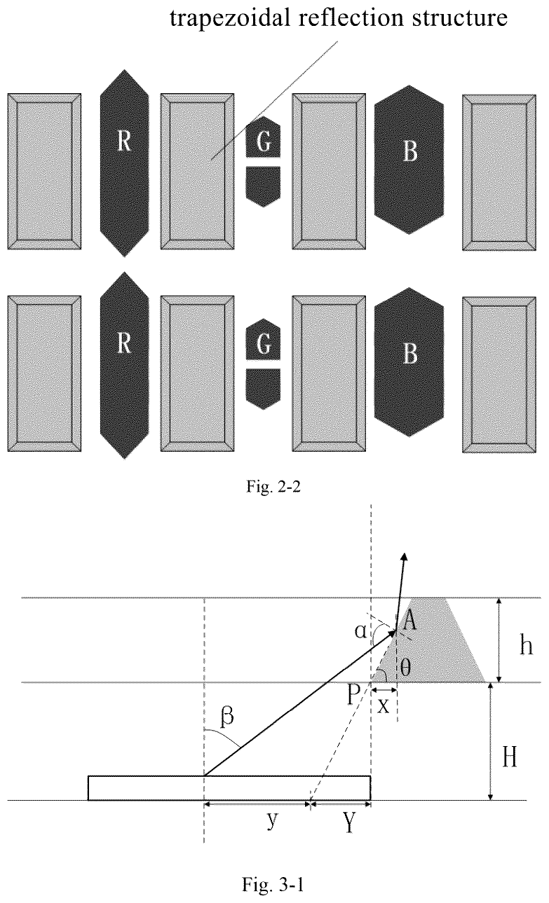

In order to improve the light transmittance of the display substrate and increase the brightness at a front viewing angle, the present disclosure provides in some embodiments a display substrate which, as shown in FIG. 2-1, includes a back plate layer 01, a pixel layer, a cathode layer 04, a thin film encapsulation (TFE) layer 05, a trapezoidal reflection structural layer 06, a low-refractive-index reflection layer 07, a high-refractive-index reflection layer 08, and a cover plate layer 09. The pixel layer includes a pixel light-emitting structure 03 and a pixel definition layer (PDL) 02.

The pixel layer is arranged on the back plate layer 01, the cathode layer 04 is arranged at a side of the pixel layer distal to the back plate layer 01, the thin film encapsulation (TFE) layer 05 is arranged at a side of the cathode layer 04 distal to the back plate layer 01, the trapezoidal reflection structural layer 06 is arranged at a side of the thin film encapsulation layer 05 distal to the back plate layer 01, an orthogonal projection of the trapezoidal reflection structural layer 06 onto the back plate layer 01 overlaps with an orthogonal projection of the pixel definition layer 02 onto the back plate layer 01, the low-refractive-index reflection layer 07 is arranged at a side of the trapezoidal reflection structural layer 06 and a side of the thin film encapsulation layer 05 distal to the back plate layer 01, and the high-refractive-index reflection layer 08 is arranged at a side of the low-refractive-index reflection layer 07 distal to the back plate layer 01.

A refractive index of the low-refractive-index reflection layer 07 is smaller than a first refractive index threshold, a refractive index of the high-refractive-index reflection layer 08 is greater than a second refractive index threshold, and the second refractive index threshold is greater than the first refractive index threshold.

The cover plate layer is a glass cover plate.

Usually, the pixel light-emitting structures include an R pixel light-emitting structure, a B pixel light-emitting structure and a G pixel light-emitting structure. The R pixel light-emitting structure emits red light, the G pixel light-emitting structure emits green light, and the B pixel light-emitting structure emits blue light. The PDL is used to separate different pixel light-emitting structures from each other.

In a possible embodiment of the present disclosure, the trapezoidal reflection structural layer includes a plurality of trapezoidal reflection structures. For example, the quantity of trapezoidal reflection structures is the same as the quantity of pixel definition layers, and a position of the trapezoidal reflection structure in a vertical direction corresponds to a position of the pixel definition layer in the vertical direction, i.e., an orthogonal projection of the trapezoidal reflection structure onto the back plate layer overlaps with the orthogonal projection of the pixel definition layer onto the back plate layer. In the embodiments of the present disclosure, the vertical direction is viewed with respect to the display substrate. As shown in FIG. 2-1, the vertical direction refers to a direction perpendicular to the film layers of the display substrate. In other words, the trapezoidal reflection structural layer is arranged at a non-light-emitting region, i.e., above the PDL. Hence, a position and a size of the trapezoidal reflection structure are determined based on a position and a size of the PDL. The size of the trapezoidal reflection structure includes a length of a lower base, a value of a base angle, and a height. As shown in FIG. 2-2 which is a top view of the display substrate, R represents the R pixel light-emitting structure, B represents the B pixel light-emitting structure, and G represents the G pixel light-emitting structure. Because the orthogonal projection of the trapezoidal reflection structure onto the back plate layer overlaps with the orthogonal projection of the PDL onto the back plate layer, the trapezoidal reflection structure is distal to the back plate layer relative to the PDL and the PDL is shielded by the trapezoidal reflection structure, the PDL is not shown in FIG. 2-2.

For example, the position of the trapezoidal reflection structure in the vertical direction is determined based on a position of the PDL in the vertical direction. In a possible embodiment of the present disclosure, a width of the lower base of the trapezoidal reflection structure is determined based on a size of an aperture of the corresponding PDL, and the size of the aperture of the PDL is a width of a lower base of the PDL. The trapezoidal reflection structure needs to be arranged at the non-light-emitting region, so the width of the lower base of the trapezoidal reflection structure is not greater than a width of the aperture of the PDL, so as to prevent the light from being shielded.

A center of the lower base of the trapezoidal reflection structure is determined based on a perpendicular bisector of the lower base of the PDL, and the center is located on the perpendicular bisector. Then, a height and a value of the base angle of the trapezoidal reflection structure are determined according to the actual situation. All the trapezoidal reflection structures may have a same size or different sizes. For example, the size of the trapezoidal reflection structure is determined based on a type of the light reaching the trapezoidal reflection structure, so as to form the trapezoidal reflection structure with different sizes at the apertures of the PDL. For clarification, the following description will be given in conjunction with another embodiment.

In a possible embodiment of the present disclosure, the trapezoidal reflection structural layer is formed through a photolithographing process. The larger the base angle (profile angle) of the trapezoidal reflection structure, the smaller the light gain. However, in a case that the base angle of the trapezoidal reflection structure is smaller than 35°, total reflection does not occur, so the base angle of the trapezoidal reflection structure layer is not smaller than 35°. A thickness of the trapezoidal reflection structure may be set according to the practical need, e.g., 1.5 μm to 4 μm.

The refractive index of the low-refractive-index reflection layer and the refractive index of the high-refractive-index reflection layer may be set according to the practical need. For example, the refractive index of the low-refractive-index reflection layer is within a range of 1.2 to 1.5, and the refractive index of the high-refractive-index reflection layer is not smaller than 1.7. For example, the refractive index of the high-refractive-index reflection layer is 1.8, and the refractive index of the low-refractive-index reflection layer is 1.4.

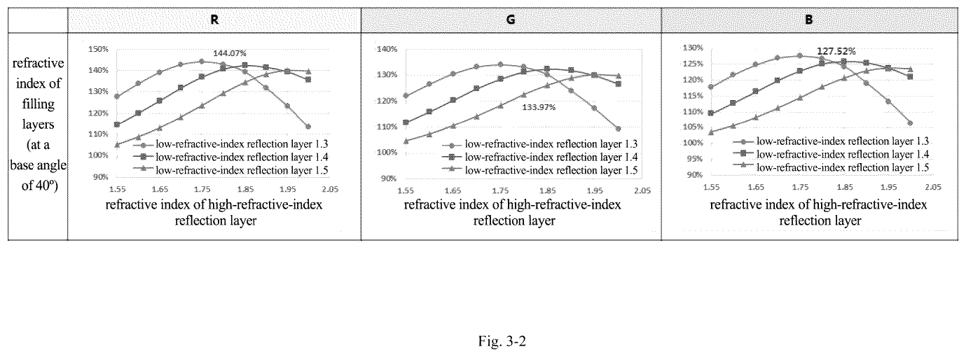

After the arrangement of the trapezoidal reflection structure, the low-refractive-index reflection layer and the high-refractive-index reflection layer, FIG. 3-1 shows a principle of an optical path. In FIG. 3-1, a divergence angle of light emitted by the pixel light-emitting structure is B, and the light reaches a side of the trapezoidal reflection structure at an angle α relative to a normal of the side of the trapezoidal reflection structure and then is reflected vertically, where H represents an overall thickness of the TFE layer, h represents a height of the trapezoidal reflection structure, θ represents an approximate profile angle of an oblique side of the trapezoidal reflection structure, i.e., the base angle of the trapezoidal reflection structure, n_high represents the refractive index of the high-refractive-index reflection layer, n_low represents the refractive index of the low-refractive-index reflection layer, y represents a transverse region in which the light emitted by the pixel light-emitting structure is capable of being totally reflected by the oblique side, Y represents a transverse region in which the light emitted by the pixel light-emitting structure is incapable of being totally reflected by the oblique side, A represents a point at which the light with the divergence angle β reaches the low-refractive-index reflection structure, P represents a point of intersection between the transverse region in which the light emitted by the pixel light-emitting structure is incapable of being totally reflected by the oblique side and the trapezoidal reflection structure, and x represents a distance between an orthogonal projection of A onto the lower base of the trapezoidal reflection structure and P.

The total reflection occurs in a case that the following conditions are met:

$$n\_high \cdot sin α = n\_low \cdot sin 90 \qquad ( 1 )$$

$$β = 18 \; 0 - α - θ \qquad ( 2 )$$

$$tan β = \frac{y + Y + x}{H + x \cdot tan θ} \qquad ( 3 )$$

$$\frac{Y}{x} = \frac{H}{x \cdot tan θ} \qquad ( 4 )$$

The trapezoidal reflection structure is arranged on the TFE, the low-refractive-index reflection layer is arranged on the trapezoidal reflection structure, the high-refractive-index reflection layer is arranged on the low-refractive-index reflection layer, and then the cover plate is attached. In a case that light is reflected by the high-refractive-index reflection layer toward the low-refractive-index reflection layer, due to a difference between the refractive indices, a part of the light is totally reflected after an incident angle is greater than a critical angle. Hence, the low-refractive-index reflection layer serves as a condensing lens to change large-angle transverse light into active forward light. As a result, it is able to improve the light transmittance of the display substrate, and increase the brightness at a front viewing angle.

In a possible embodiment of the present disclosure, in a plane perpendicular to the back plate layer, the trapezoidal reflection structural layer includes a plurality of trapezoidal reflection structures, each of the trapezoidal reflection structures includes a lower base proximate to the back plate layer and an upper base distal to the back plate layer, and a length of the upper base is smaller than a length of the lower base.

Different pixel light-emitting structures are separated from each other through a plurality of PDLs, so the display substrate includes a plurality of non-light-emitting regions. The trapezoidal reflection structure is arranged at each non-light-emitting region. For example, the quantity of trapezoidal reflection structures is the same as the quantity of PDLs.

For each trapezoidal reflection structure, its lower base is arranged proximate to the back plate layer, its upper base is arranged distal to the back plate layer, and the length of the upper base is smaller than the length of the lower base. For example, the length of the lower base of the trapezoidal reflection structure is determined based on a size of the aperture of the PDL (i.e., a length of a lower base of the PDL). For example, the length of the lower base of the trapezoidal reflection structure is not greater than the length of the lower base of the PDL.

In a possible embodiment of the present disclosure, the refractive index of the low-refractive-index reflection layer is within a range of 1.2 to 1.5.

The refractive index of the low-refractive-index reflection layer is 1.2 to 1.5. For example, the low-refractive-index reflection layer includes SiO₂, LiF or MgF₂, i.e., the low-refractive-index reflection layer is made of SiO₂, LiF or MgF₂ and formed through Chemical Vapor Deposition (CVD) or evaporation conveniently.

In a possible embodiment of the present disclosure, a difference between the refractive index of the high-refractive-index reflection layer and the refractive index of the low-refractive-index reflection layer is not smaller than 0.3.

The refractive index of the high-refractive-index reflection layer needs to be greater than the refractive index of the low-refractive-index reflection layer, and the difference therebetween is not smaller than 0.3. For example, the refractive index of the high-refractive-index reflection layer is greater than 1.7.

The high-refractive-index reflection layer is a reflection layer made of an adhesive doped with high-refractive-index particles, e.g., ZrO₂. The high-refractive-index reflection layer is formed through spinning, printing, or coating.

FIG. 3-2 shows a simulation result of the light transmittance of the display substrate in a case that the lower base of the trapezoidal reflection structure is 40, filling layers (the high-refractive-index layer and the low-refractive-index layer) have different refractive indices and the red light, the green light and the blue light is reflected by the high-refractive-index reflection layer toward the low-refractive-index reflection layer.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures.

A length of a lower base of the trapezoidal reflection structure corresponding to the B pixel light-emitting structure is not smaller than a length of a lower base of the trapezoidal reflection structure corresponding to the R pixel light-emitting structure, and the length of the lower base of the trapezoidal reflection structure corresponding to the R pixel light-emitting structure is not smaller than a length of a lower base of the trapezoidal structure corresponding to the G pixel light-emitting structure.

For each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

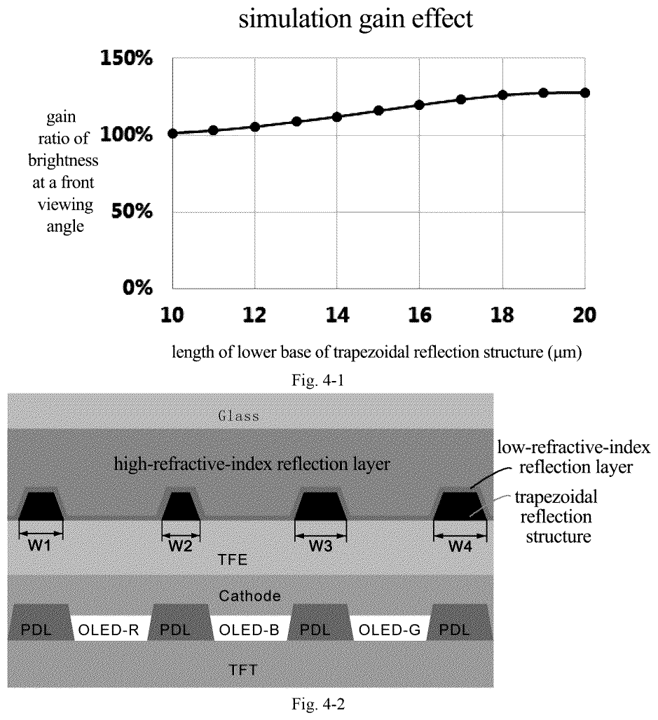

Usually, a brightness ratio among the red light, the green light and the blue light needs to be 3:6:1 to achieve white balance. In an OLED element, the luminous efficiency of the blue light is the lowest, while the luminous efficiency of the green light is the highest. FIG. 4-1 shows a simulation gain effect. As shown in FIG. 4-1, the larger the space occupied by the trapezoidal reflection structure, i.e., the longer the lower base of the trapezoidal reflection structure, the larger the light gain.

For each pixel light-emitting structure, the trapezoidal reflection structure corresponding the pixel light-emitting structure is determined based on the pixel definition layer at the first side of the pixel light-emitting structure. To be specific, a trapezoidal reflection structure corresponding to the pixel definition layer at the first side of the pixel light-emitting structure in the vertical direction is selected as the trapezoidal reflection structure corresponding to the pixel light-emitting structure. In a case that there are pixel light-emitting structures at both sides of the pixel definition layer, as shown in FIG. 4-2, the first side is a left side or a right side of the pixel light-emitting structure in an extension direction of the film layer of the display substrate. To be specific, the first side may be set according to the practical need. In a case that there is merely one pixel light-emitting structure at both sides of the pixel definition layer, i.e., in a case that the light emitted by the pixel light-emitting structure is merely reflected by one trapezoidal reflection structure, the trapezoidal reflection structure is selected as the trapezoidal reflection structure corresponding to the pixel light-emitting structure. The first side of the pixel light-emitting structure may be determined according to the practical need, and will not be particularly defined herein.

After determining the trapezoidal reflection structure corresponding to the pixel light-emitting structure, the length of the lower base of the trapezoidal reflection structure is adjusted based on a type of the pixel light-emitting structure, so as to adjust the luminous efficiency of the red light, the green light and the blue light. To be specific, the length of the lower base of the trapezoidal reflection structure corresponding to the B pixel light-emitting structure is not smaller than the length of the lower base of the trapezoidal reflection structure corresponding to the R pixel light-emitting structure, and the length of the lower base of the trapezoidal reflection structure corresponding to the R pixel light-emitting structure is not smaller than the length of the lower base of the trapezoidal structure corresponding to the G pixel light-emitting structure, so as to increase the luminous efficiency of the blue light and the red light, thereby to achieve the white balance.

For example, as shown in FIG. 4-2, the display substrate includes a TFT layer, a PDL, an OLED-R, an OLED-G, an OLED-B, a TFE layer, a trapezoidal reflection structure, a low-refractive-index reflection layer, a high-refractive-index reflection layer, and a glass cover plate layer. For each pixel light-emitting structure, the trapezoidal reflection structure corresponding to the pixel light-emitting structure is a trapezoidal reflection structure corresponding to the pixel definition layer at a left side of the pixel light-emitting structure in the vertical direction. There are four trapezoidal reflection structures from left to right. A first trapezoidal reflection structure corresponds to the pixel light-emitting structure OLED-R, so the length of the lower base of the first trapezoidal reflection structure is determined as W1 based on the red light. A second trapezoidal reflection structure corresponds to the pixel light-emitting structure OLED-G, so the length of the lower base of the second trapezoidal reflection structure is determined as W2 based on the green light. A third trapezoidal reflection structure corresponds to the pixel light-emitting structure OLED-B, so the length of the lower base of the third trapezoidal reflection structure is determined as W3 based on the blue light. A fourth trapezoidal reflection structure is merely used to reflect the blue light, so the length of the lower base of the fourth trapezoidal reflection structure is determined as W4 based on the blue light. W2≤W1≤W3.

In a possible embodiment of the present disclosure, the length of the lower base of the pixel definition layer is pitch, and ½ pitch≤W2≤W1≤W3≤pitch.

After determining the length of the lower base of the trapezoidal reflection structure, a position of the lower base of the trapezoidal reflection structure may be determined based on the perpendicular bisector of the lower base of the PDL. The center of the lower base of the trapezoidal reflection structure is located on the perpendicular bisector of the lower base of the PDL. A value of the base angle and the height of the trapezoidal reflection structure may be set according to the practical need.

For example, in a photolithographing process, different trapezoidal structures are formed at the apertures of the pixel definition layers using different masks. Through optimizing the structure, it is able to optimize the white balance, increase the brightness and color gamut, reduce the power consumption of the OLED element, and meet the requirement on a high-resolution product.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures.

A base angle of the trapezoidal reflection structure corresponding to the B pixel light-emitting structure is not greater than a base angle of the trapezoidal reflection structure corresponding to the R pixel light-emitting structure, the base angle of the trapezoidal reflection structure corresponding to the R pixel light-emitting structure is not greater than a base angle of the trapezoidal structure corresponding to the G pixel light-emitting structure, and two base angles of the trapezoidal reflection structure are equal.

For each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

Usually, a brightness ratio among the red light, the green light and the blue light needs to be 3:6:1 to achieve white balance. In an OLED element, the luminous efficiency of the blue light is the lowest, while the luminous efficiency of the green light is the highest.

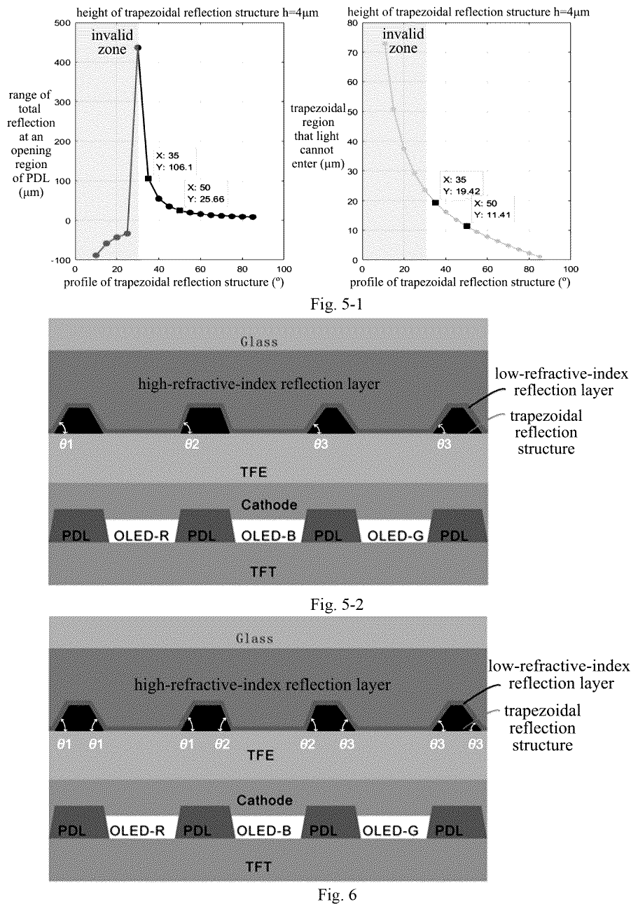

FIG. 5-1 shows a simulation gain effect. As shown in FIG. 5-1, the larger the base angle (profile angle) of the trapezoidal reflection structure, the smaller the light gain. Hence, for each pixel light-emitting structure, the value of the base angle of the trapezoidal reflection structure corresponding to the pixel light-emitting structure is set, so as to adjust the luminous efficiency of the red light, the green light and the blue light.

For each pixel light-emitting structure, the trapezoidal reflection structure corresponding the pixel light-emitting structure is determined based on the pixel definition layer at the first side of the pixel light-emitting structure. To be specific, a trapezoidal reflection structure corresponding to the pixel definition layer at the first side of the pixel light-emitting structure in the vertical direction is selected as the trapezoidal reflection structure corresponding to the pixel light-emitting structure. In a case that there are pixel light-emitting structures at both sides of the pixel definition layer, as shown in FIG. 5-2, the first side is a left side or a right side of the pixel light-emitting structure in an extension direction of the film layer of the display substrate. To be specific, the first side may be set according to the practical need. In a case that there is merely one pixel light-emitting structure at both sides of the pixel definition layer, i.e., in a case that the light emitted by the pixel light-emitting structure is merely reflected by one trapezoidal reflection structure, the trapezoidal reflection structure is selected as the trapezoidal reflection structure corresponding to the pixel light-emitting structure. The first side of the pixel light-emitting structure may be determined according to the practical need, and will not be particularly defined herein.

After determining the trapezoidal reflection structure corresponding to the pixel light-emitting structure, the value of the base angle of the trapezoidal reflection structure is set based on a type of the pixel light-emitting structure, the trapezoidal reflection structure is of an isosceles trapezoid-like shape, i.e., the two base angles are equal. The base angle of the trapezoidal reflection structure corresponding to the B pixel light-emitting structure is not greater than the base angle of the lower base of the trapezoidal reflection structure corresponding to the R pixel light-emitting structure, and the base angle of the trapezoidal reflection structure corresponding to the R pixel light-emitting structure is not greater than the base angle of the trapezoidal structure corresponding to the G pixel light-emitting structure, so as to increase the luminous efficiency of the blue light and the red light, thereby to achieve the white balance.

For example, as shown in FIG. 5-2, the display substrate includes a TFT layer, a PDL, an OLED-R, an OLED-G, an OLED-B, a TFE layer, a trapezoidal reflection structure, a low-refractive-index reflection layer, a high-refractive-index reflection layer, and a glass cover plate layer. For each pixel light-emitting structure, the trapezoidal reflection structure corresponding to the pixel light-emitting structure is a trapezoidal reflection structure corresponding to the pixel definition layer at a left side of the pixel light-emitting structure in the vertical direction. There are four trapezoidal reflection structures from left to right. A first trapezoidal reflection structure corresponds to the pixel light-emitting structure OLED-R, so the base angle of the first trapezoidal reflection structure is determined as θ1 based on the red light. A second trapezoidal reflection structure corresponds to the pixel light-emitting structure OLED-G, so the base angle of the second trapezoidal reflection structure is determined as θ2 based on the green light. A third trapezoidal reflection structure corresponds to the pixel light-emitting structure OLED-B, so the base angle of the third trapezoidal reflection structure is determined as θ3 based on the blue light. A fourth trapezoidal reflection structure is merely used to reflect the blue light, so the base angle of the fourth trapezoidal reflection structure is determined as θ3 based on the blue light, where θ3≤θ1≤θ2. After determining the base angle of the trapezoidal reflection structure, the trapezoidal reflection structure may be set based on a predetermined length of the lower base of the trapezoidal reflection structure and a height of the trapezoidal reflection structure. For example, 35°≤θ3≤θ1≤θ2≤80°.

Through adjusting the base angle of the trapezoidal reflection structure, it is able to optimize the structure of the display substrate, optimize the white balance, increase the brightness and color gamut, reduce the power consumption of the OLED element, and meet the requirement on a high-resolution product.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures.

A base angle of the B pixel light-emitting structure is not greater than a base angle of the R pixel light-emitting structure, and the base angle of the R pixel light-emitting structure is not greater than a base angle of the G pixel light-emitting structure.

For each of the pixel light-emitting structures, the base angles of the pixel light-emitting structure include a second-side base angle of the trapezoidal reflection structure corresponding to the pixel definition layer at a first side of the pixel light-emitting structure in a vertical direction and a first-side base angle of the trapezoidal reflection structure corresponding to the pixel definition layer at a second side of the pixel light-emitting structure in the vertical direction.

A base angle of the B pixel light-emitting structure is not greater than a base angle of the R pixel light-emitting structure, and the base angle of the R pixel light-emitting structure is not greater than a base angle of the G pixel light-emitting structure.

For each of the pixel light-emitting structures, the base angles of the pixel light-emitting structure include a second-side base angle of the trapezoidal reflection structure corresponding to the pixel definition layer at a first side of the pixel light-emitting structure in a vertical direction and a first-side base angle of the trapezoidal reflection structure corresponding to the pixel definition layer at a second side of the pixel light-emitting structure in the vertical direction. For each of the pixel definition layers, an orthogonal projection of the trapezoidal reflection structure corresponding to the pixel definition layer in the vertical direction to the back plate layer overlaps with an orthogonal projection of the pixel definition layer onto the back plate layer.

Usually, a brightness ratio among the red light, the green light and the blue light needs to be 3:6:1 to achieve white balance. In an OLED element, the luminous efficiency of the blue light is the lowest, while the luminous efficiency of the green light is the highest.

The larger the base angle (profile angle) of the trapezoidal reflection structure, the smaller the light gain. Hence, for each pixel light-emitting structure, the value of the base angle of the trapezoidal reflection structure corresponding to the pixel light-emitting structure is set, so as to adjust the luminous efficiency of the red light, the green light and the blue light.

The trapezoidal reflection structure corresponds to the pixel definition layer in the vertical direction, and different pixel light-emitting structures are separated from each other through the pixel definition layers, so two types of light may reach one trapezoidal reflection structure, and the values of the base angles of the trapezoidal structure needs to be determined based on the types of the light. In order to determine the base angle of the trapezoidal reflection structure, for each pixel light-emitting structure, the base angles of the pixel light-emitting structure include the second-side base angle of the trapezoidal reflection structure corresponding to the pixel definition layer the first side of the pixel light-emitting structure in the vertical direction and the first-side base angle of the trapezoidal reflection structure corresponding to the pixel definition layer at the second side of the pixel light-emitting structure in the vertical direction. The first-side base angle is different from the second-side base angle. For each trapezoidal reflection structure, in a case that there is no pixel definition layer corresponding to one base angle, a value of this base angle is equal to a value of the other base angle.

After determining the trapezoidal reflection structure corresponding to the pixel light-emitting structure, the base angles of the trapezoidal reflection structures are set based on the type of the pixel light-emitting structure. The base angle of the trapezoidal reflection structure corresponding to the B pixel light-emitting structure is not greater than the base angle of the trapezoidal reflection structure corresponding to the R pixel light-emitting structure, and the base angle of the trapezoidal reflection structure corresponding to the R pixel light-emitting structure is not greater than the base angle of the trapezoidal reflection structure corresponding to the G pixel light-emitting structure. In this way, it is able to increase the luminous efficiency of the blue light and the red light, thereby to achieve the white balance.

For example, as shown in FIG. 6, the display substrate includes a TFT layer, a PDL, an OLED-R, an OLED-G, an OLED-B, a TFE layer, a trapezoidal reflection structure, a low-refractive-index reflection layer, a high-refractive-index reflection layer, and a glass cover plate layer. For each pixel light-emitting structure, the trapezoidal reflection structure corresponding to the pixel light-emitting structure is a trapezoidal reflection structure corresponding to the pixel definition layer at a left side of the pixel light-emitting structure in the vertical direction. There are four trapezoidal reflection structures from left to right. For a second trapezoidal reflection structure, a base angle at the left corresponds to OLED-R, and a base angle at the right corresponds to OLED-G, so a value of the base angle at the left is determined as θ1 based on the red light, and a value of the base angle at the right is determined as θ2 based on the green light, where θ3≤θ1≤θ2. After determining the base angles of the trapezoidal reflection structure, the trapezoidal reflection structure may be set based on a predetermined length of the lower base of the trapezoidal reflection structure and a height of the trapezoidal reflection structure.

Through adjusting the base angles of the trapezoidal reflection structure, it is able to optimize the structure of the display substrate, optimize the white balance, increase the brightness and color gamut, reduce the power consumption of the OLED element, and meet the requirement on a high-resolution product.

In a possible embodiment of the present disclosure, the pixel light-emitting structure includes an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer includes a plurality of trapezoidal reflection structures.

A height of the trapezoidal reflection structure corresponding to the B pixel light-emitting structure is not smaller than a height of the trapezoidal reflection structure corresponding to the R pixel light-emitting structure, and the height of the trapezoidal reflection structure corresponding to the R pixel light-emitting structure is not smaller than a height of the trapezoidal reflection structure corresponding to the G pixel light-emitting structure.

For each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

Usually, a brightness ratio among the red light, the green light and the blue light needs to be 3:6:1 to achieve white balance. In an OLED element, the luminous efficiency of the blue light is the lowest, while the luminous efficiency of the green light is the highest.

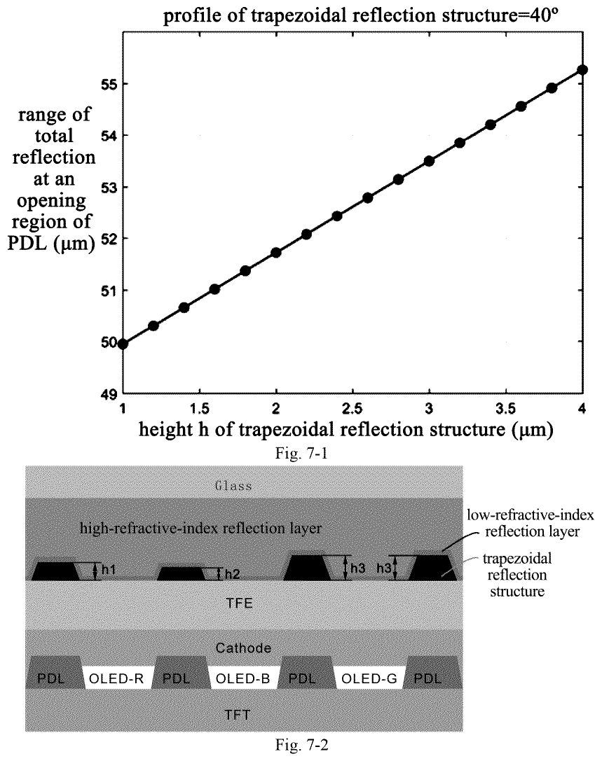

FIG. 7-1 shows a simulation gain effect. As shown in FIG. 7-1, the larger the height of the trapezoidal reflection structure, the larger the light gain. Hence, for each pixel light-emitting structure, the height of the trapezoidal reflection structure corresponding to the pixel light-emitting structure is set, so as to adjust the luminous efficiency of the red light, the green light and the blue light.

For each pixel light-emitting structure, the trapezoidal reflection structure corresponding the pixel light-emitting structure is determined based on the pixel definition layer at the first side of the pixel light-emitting structure. To be specific, a trapezoidal reflection structure corresponding to the pixel definition layer at the first side of the pixel light-emitting structure in the vertical direction is selected as the trapezoidal reflection structure corresponding to the pixel light-emitting structure. In a case that there are pixel light-emitting structures at both sides of the pixel definition layer, as shown in FIG. 6, the first side is a left side or a right side of the pixel light-emitting structure in an extension direction of the film layer of the display substrate. To be specific, the first side may be set according to the practical need. In a case that there is merely one pixel light-emitting structure at both sides of the pixel definition layer, i.e., in a case that the light emitted by the pixel light-emitting structure is merely reflected by one trapezoidal reflection structure, the trapezoidal reflection structure is selected as the trapezoidal reflection structure corresponding to the pixel light-emitting structure. The first side of the pixel light-emitting structure may be determined according to the practical need, and will not be particularly defined herein.

After determining the trapezoidal reflection structure corresponding to the pixel light-emitting structure, the height of the trapezoidal reflection structure is set based on a type of the pixel light-emitting structure. The height of the trapezoidal reflection structure corresponding to the B pixel light-emitting structure is not smaller than the height of the lower base of the trapezoidal reflection structure corresponding to the R pixel light-emitting structure, and the height of the trapezoidal reflection structure corresponding to the R pixel light-emitting structure is not smaller than the height of the trapezoidal structure corresponding to the G pixel light-emitting structure, so as to increase the luminous efficiency of the blue light and the red light, thereby to achieve the white balance.

For example, as shown in FIG. 7-2, the display substrate includes a TFT layer, a PDL, an OLED-R, an OLED-G, an OLED-B, a TFE layer, a trapezoidal reflection structure, a low-refractive-index reflection layer, a high-refractive-index reflection layer, and a glass cover plate layer. For each pixel light-emitting structure, the trapezoidal reflection structure corresponding to the pixel light-emitting structure is a trapezoidal reflection structure corresponding to the pixel definition layer at a left side of the pixel light-emitting structure in the vertical direction. There are four trapezoidal reflection structures from left to right. A first trapezoidal reflection structure corresponds to the pixel light-emitting structure OLED-R, so the height of the first trapezoidal reflection structure is determined as h1 based on the red light. A second trapezoidal reflection structure corresponds to the pixel light-emitting structure OLED-G, so the height of the second trapezoidal reflection structure is determined as h2 based on the green light. A third trapezoidal reflection structure corresponds to the pixel light-emitting structure OLED-B, so the height of the third trapezoidal reflection structure is determined as h3 based on the blue light. A fourth trapezoidal reflection structure is merely used to reflect the blue light, so the height of the fourth trapezoidal reflection structure is determined as h3 based on the blue light, where h2≤h1≤h3. For example, 1 μm≤h2≤h1≤h3≤10 μm. After determining the height of the trapezoidal reflection structure, the trapezoidal reflection structure may be set based on a predetermined length of the lower base of the trapezoidal reflection structure and base angles of the trapezoidal reflection structure. For example, 35°≤θ3≤θ1≤θ2≤80°.

Through adjusting the height of the trapezoidal reflection structure, it is able to optimize the structure of the display substrate, optimize the white balance, increase the brightness and color gamut, reduce the power consumption of the OLED element, and meet the requirement on a high-resolution product.

Based on the above embodiments of the present disclosure, the height, the length of the lower base and the values of the two base angles of each trapezoidal reflection structure may be adjusted based on the corresponding pixel light-emitting structure, so as to optimize the structure of the display substrate, optimize the white balance, increase the brightness and color gamut, reduce the power consumption of the OLED element, and meet the requirement on a high-resolution product.

It should be further appreciated that, such words as “first” and “second” are merely used to separate one entity or operation from another entity or operation, but are not necessarily used to represent or imply any relation or order between the entities or operations. In addition, such terms as “include” or “including” or any other variations involved in the present disclosure intend to provide non-exclusive coverage, so that a procedure, method, article or device including a series of elements may also include any other elements not listed herein, or may include any inherent elements of the procedure, method, article or device. If without any further limitations, for the elements defined by such sentence as “including one . . . ”, it is not excluded that the procedure, method, article or device including the elements may also include any other identical elements.

The above embodiments are described in a related manner, and the same or similar contents in the embodiments are not repeated, i.e., each embodiment merely focuses on the difference from the others.

The above are merely the preferred embodiments of the present disclosure, but shall not be construed as limiting the scope of the present disclosure. Any modifications, equivalents or improvements made within the spirit and principle of the present disclosure shall fall within the scope of the present disclosure.

1. A display substrate, comprising a back plate layer, a pixel layer, a cathode layer, a thin film encapsulation layer, a trapezoidal reflection structural layer, a low-refractive-index reflection layer, a high-refractive-index reflection layer, and a cover plate layer,
wherein the pixel layer comprises a pixel light-emitting structure and a pixel definition layer;
the pixel layer is arranged on the back plate layer, the cathode layer is arranged at a side of the pixel layer distal to the back plate layer, the thin film encapsulation layer is arranged at a side of the cathode layer distal to the back plate layer, the trapezoidal reflection structural layer is arranged at a side of the thin film encapsulation layer distal to the back plate layer, an orthogonal projection of the trapezoidal reflection structural layer onto the back plate layer overlaps with an orthogonal projection of the pixel definition layer onto the back plate layer, the low-refractive-index reflection layer is arranged at a side of the trapezoidal reflection structural layer and a side of the thin film encapsulation layer distal to the back plate layer, and the high-refractive-index reflection layer is arranged at a side of the low-refractive-index reflection layer distal to the back plate layer; and
a refractive index of the low-refractive-index reflection layer is smaller than a first refractive index threshold, a refractive index of the high-refractive-index reflection layer is greater than a second refractive index threshold, and the second refractive index threshold is greater than the first refractive index threshold.

2. The display substrate according to claim 1, wherein in a plane perpendicular to the back plate layer, the trapezoidal reflection structural layer comprises a plurality of trapezoidal reflection structures, each of the trapezoidal reflection structures comprises a lower base proximate to the back plate layer and an upper base distal to the back plate layer, and a length of the upper base is smaller than a length of the lower base.

3. The display substrate according to claim 1, wherein the refractive index of the low-refractive-index reflection layer is within a range of 1.2 to 1.5.

4. The display substrate according to claim 1, wherein the refractive index of the high-refractive-index reflection layer is not smaller than 1.7.

5. The display substrate according to claim 1, wherein a difference between the refractive index of the high-refractive-index reflection layer and the refractive index of the low-refractive-index reflection layer is not smaller than 0.3.

6. The display substrate according to claim 5, wherein the low-refractive-index reflection layer comprises SiO₂, LiF or MgF₂.

7. The display substrate according to claim 1, wherein the pixel light-emitting structure comprises an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer comprises a plurality of trapezoidal reflection structures;
a length of a lower base of the trapezoidal reflection structure corresponding to the B pixel light-emitting structure is not smaller than a length of a lower base of the trapezoidal reflection structure corresponding to the R pixel light-emitting structure, and the length of the lower base of the trapezoidal reflection structure corresponding to the R pixel light-emitting structure is not smaller than a length of a lower base of the trapezoidal structure corresponding to the G pixel light-emitting structure; and
for each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

8. The display substrate according to claim 7, wherein ½ pitch≤W2≤W1≤W3≤pitch, where W1 represents the length of the lower base of the trapezoidal reflection structure corresponding to the R pixel light-emitting structure, W2 represents the length of the lower base of the trapezoidal reflection structure corresponding to the G pixel light-emitting structure, W3 represents the length of the lower base of the trapezoidal reflection structure corresponding to the B pixel light-emitting structure, and pitch represents a length of a lower base of the pixel definition layer.

9. The display substrate according to claim 1, wherein the pixel light-emitting structure comprises an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer comprises a plurality of trapezoidal reflection structures;
a base angle of the trapezoidal reflection structure corresponding to the B pixel light-emitting structure is not greater than a base angle of the trapezoidal reflection structure corresponding to the R pixel light-emitting structure, the base angle of the trapezoidal reflection structure corresponding to the R pixel light-emitting structure is not greater than a base angle of the trapezoidal structure corresponding to the G pixel light-emitting structure, and two base angles of the trapezoidal reflection structure are equal; and
for each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

10. The display substrate according to claim 9, wherein 35°≤θ3≤θ1≤θ2≤80°, where θ1 represents the base angle of the trapezoidal reflection structure corresponding to the R pixel light-emitting structure, θ2 represents the base angle of the trapezoidal reflection structure corresponding to the G pixel light-emitting structure, and θ3 represents the base angle of the trapezoidal reflection structure corresponding to the B pixel light-emitting structure.

11. The display substrate according to claim 1, wherein the pixel light-emitting structure comprises an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer comprises a plurality of trapezoidal reflection structures;
a base angle of the B pixel light-emitting structure is not greater than a base angle of the R pixel light-emitting structure, and the base angle of the R pixel light-emitting structure is not greater than a base angle of the G pixel light-emitting structure; and
for each of the pixel light-emitting structures, the base angles of the pixel light-emitting structure comprise a second-side base angle of the trapezoidal reflection structure corresponding to the pixel definition layer at a first side of the pixel light-emitting structure in a vertical direction and a first-side base angle of the trapezoidal reflection structure corresponding to the pixel definition layer at a second side of the pixel light-emitting structure in the vertical direction, and for each of the pixel definition layers, an orthogonal projection of the trapezoidal reflection structure corresponding to the pixel definition layer in the vertical direction to the back plate layer overlaps with an orthogonal projection of the pixel definition layer onto the back plate layer.

12. The display substrate according to claim 1, wherein the pixel light-emitting structure comprises an R pixel light-emitting structure, a G pixel light-emitting structure and a B pixel light-emitting structure, the R pixel light-emitting structure emits red light, the G pixel light-emitting structure emits green light, the B pixel light-emitting structure emits blue light, and the trapezoidal reflection structural layer comprises a plurality of trapezoidal reflection structures;
a height of the trapezoidal reflection structure corresponding to the B pixel light-emitting structure is not smaller than a height of the trapezoidal reflection structure corresponding to the R pixel light-emitting structure, and the height of the trapezoidal reflection structure corresponding to the R pixel light-emitting structure is not smaller than a height of the trapezoidal reflection structure corresponding to the G pixel light-emitting structure; and
for each of the pixel light-emitting structures, an orthogonal projection of the trapezoidal reflection structure corresponding to the pixel light-emitting structure onto the back plate layer overlaps with an orthogonal projection of the pixel definition layer at a first side of the pixel light-emitting structure onto the back plate layer.

13. The display substrate according to claim 12, wherein 1 μm≤h2≤h1≤h3≤10 μm, where h1 represents the height of the trapezoidal reflection structure corresponding to the R pixel light-emitting structure, h2 represents the height of the trapezoidal reflection structure corresponding to the G pixel light-emitting structure, and h3 represents the height of the trapezoidal reflection structure corresponding to the B pixel light-emitting structure.

14. A display screen, comprising a display substrate, wherein the display substrate comprises a back plate layer, a pixel layer, a cathode layer, a thin film encapsulation layer, a trapezoidal reflection structural layer, a low-refractive-index reflection layer, a high-refractive-index reflection layer, and a cover plate layer,
wherein the pixel layer comprises a pixel light-emitting structure and a pixel definition layer;
the pixel layer is arranged on the back plate layer, the cathode layer is arranged at a side of the pixel layer distal to the back plate layer, the thin film encapsulation layer is arranged at a side of the cathode layer distal to the back plate layer, the trapezoidal reflection structural layer is arranged at a side of the thin film encapsulation layer distal to the back plate layer, an orthogonal projection of the trapezoidal reflection structural layer onto the back plate layer overlaps with an orthogonal projection of the pixel definition layer onto the back plate layer, the low-refractive-index reflection layer is arranged at a side of the trapezoidal reflection structural layer and a side of the thin film encapsulation layer distal to the back plate layer, and the high-refractive-index reflection layer is arranged at a side of the low-refractive-index reflection layer distal to the back plate layer; and
a refractive index of the low-refractive-index reflection layer is smaller than a first refractive index threshold, a refractive index of the high-refractive-index reflection layer is greater than a second refractive index threshold, and the second refractive index threshold is greater than the first refractive index threshold.

15. The display substrate according to claim 2, wherein a difference between the refractive index of the high-refractive-index reflection layer and the refractive index of the low-refractive-index reflection layer is not smaller than 0.3.

16. The display substrate according to claim 3, wherein a difference between the refractive index of the high-refractive-index reflection layer and the refractive index of the low-refractive-index reflection layer is not smaller than 0.3.

17. The display substrate according to claim 4, wherein a difference between the refractive index of the high-refractive-index reflection layer and the refractive index of the low-refractive-index reflection layer is not smaller than 0.3.

18. The display screen according to claim 14, wherein in a plane perpendicular to the back plate layer, the trapezoidal reflection structural layer comprises a plurality of trapezoidal reflection structures, each of the trapezoidal reflection structures comprises a lower base proximate to the back plate layer and an upper base distal to the back plate layer, and a length of the upper base is smaller than a length of the lower base.

19. The display screen according to claim 14, wherein the refractive index of the low-refractive-index reflection layer is within a range of 1.2 to 1.5.

20. The display screen according to claim 14, wherein the refractive index of the high-refractive-index reflection layer is not smaller than 1.7.
